(19) United States
(12) Patent Application Publication
(10) Pub. No.: US 2025/0120017 A1
(43) Pub. Date: Apr. 10, 2025

(54) Contact Hole Assembly and Electronic Device

(71) Applicant: LG Display Co., Ltd., Seoul (KR)

(72) Inventor: Hyeon-Sik Cho, Paju-si (KR)

(21) Appl. No.: 18/904,494

(22) Filed: Oct. 2, 2024

(30) Foreign Application Priority Data
Oct. 4, 2023 (KR) 10-2023-0131384

(51) Int. Cl. H05K 1/11

(52) U.S. Cl. CPC H05K 1/115; H05K 2201/09645; H05K 2201/10128

(57) ABSTRACT

Embodiments of the disclosure relate to a contact hole assembly and an electronic device and may, more specifically, provide a contact hole assembly comprising a first metal layer to which an electrical signal is input, an insulation layer formed on the first metal layer, a second metal layer formed on the insulation layer and outputting the electrical signal, and a contact hole electrically connecting the first metal layer and the second metal layer, wherein the contact hole includes a via area penetrating the insulation layer, a conductor formed in the via area, and a recess area where a portion of a surface of the conductor is removed.

### CROSS-REFERENCE TO RELATED APPLICATION

This application claims priority from Republic of Korea Patent Application No. 10-2023-0131384, filed on Oct. 4, 2023, which is hereby incorporated by reference in its entirety.

### BACKGROUND

### Field

Embodiments of the disclosure relate to a contact hole assembly and electronic device and, more specifically, to a contact hole assembly and electronic device that may enhance impedance matching characteristics.

### Description of Related Art

An electronic device is a device that is driven by receiving electrical energy from the outside of the electronic device, and may have various circuits and metal layers for driving formed inside.

A representative example of electronic devices may be a communication device that communicates wireless signals or a display device that displays images through a display panel. Various types of display devices, such as liquid crystal displays (LCDs), organic light emitting displays (OLEDs), etc. are being utilized, depending on the configuration of the display panel.

The electronic devices may include contact holes for connecting lines formed of metal. The contact hole may be formed to penetrate at least one insulation layer formed on a first metal layer to expose at least a portion of the first metal layer, and a second metal layer formed on the insulation layer may be electrically connected to the first metal layer through the contact hole.

In this case, as the electronic device slims down, the gap between the first metal layer and the second metal layer decreases, and the capacitance between the first metal layer and the second metal layer increases. As a result, the impedance of the printed circuit board on which the first metal layer and the second metal layer are formed may decrease, making impedance matching difficult.

### SUMMARY

Accordingly, the inventors of the disclosure have invented a contact hole assembly and electronic device with enhanced impedance matching characteristics.

Embodiments of the disclosure may provide a contact hole assembly and electronic device that may enhance low power consumption and impedance matching characteristics by forming a recess structure inside the contact hole.

Embodiments of the disclosure may provide a contact hole assembly and electronic device that may enhance signal transmission efficiency and impedance matching characteristics by removing the stub area of the contact hole.

Embodiments of the disclosure may provide a contact hole assembly comprising: a first metal layer that receives an electrical signal; an insulation layer on the first metal layer; a second metal layer on the insulation layer such that the insulation layer is between the first metal layer and the second metal layer, the second metal layer outputting the electrical signal; and a contact hole that electrically connects the first metal layer and the second metal layer, the contact hole including: a via area that penetrates through a thickness of the insulation layer; a conductor in the via area; and a recess area in the conductor where a portion of a surface of the conductor is indented in a direction away from the via area.

Embodiments of the disclosure may provide a contact hole assembly, comprising: a first metal layer that receives an electrical signal; an insulation layer on the first metal layer; a second metal layer on the insulation layer such that the insulation layer is between the first metal layer and the second metal layer, the second metal layer outputting the electrical signal; and a contact hole through the insulation layer, the contact hole electrically connecting the first metal layer and the second metal layer, wherein the contact hole includes a conductor that is connected to the first metal layer and the second metal layer and extends from the second metal layer to the first metal layer whereas the contact hole extends from the second metal layer past the first metal layer.

In one embodiment, an electronic device comprises: a first metal layer that receives an electrical signal; a first insulation layer on the first metal layer; a second metal layer on the first insulation layer such that the first insulation layer is between the first metal layer and the second metal layer, the second metal layer outputting the electrical signal; and a contact hole that electrically connects the first metal layer and the second metal layer, the contact hole including: a via area that penetrates through a thickness of the first insulation layer; a conductor in the via area; and a recess area that extends from an inner surface of the conductor toward an outer surface of the conductor, wherein a width of a portion of the conductor having the recess area is less than a width of a portion of the conductor that lacks the recess area.

According to embodiments of the disclosure, there may be provided a contact hole assembly and electronic device with enhanced impedance matching characteristics.

There may be provided a contact hole assembly and electronic device that may enhance low power and impedance matching characteristics by forming a recess structure inside the contact hole.

There may be provided a contact hole assembly and electronic device that may enhance signal transmission efficiency and impedance matching characteristics by removing the stub area of the contact hole.

### BRIEF DESCRIPTION OF DRAWINGS

The above and other objects, features, and advantages of the disclosure will be more clearly understood from the following detailed description, taken in conjunction with the accompanying drawings, in which:

FIG. 1 is a view illustrating a display device as an example of an electronic device including a contact hole assembly;

FIG. 2 is an example graph obtained by measuring the impedance of a printed circuit board in a time domain;

FIG. 3 is an example cross-sectional view illustrating a contact hole assembly according to embodiments of the disclosure;

FIG. 4 is an example view illustrating a process of forming a contact hole assembly according to embodiments;

FIG. 5 is an example graph illustrating a change in impedance according to a recess area ratio in a contact hole assembly according to embodiments;

FIGS. 6 and 7 are example views illustrating a shape of a contact hole according to embodiments;

FIG. 8 is an example cross-sectional view illustrating a signal transmission path in a contact hole assembly according to embodiments;

FIG. 9 is an example view illustrating a process of removing a stub area in a contact hole assembly according to embodiments;

FIG. 10 is an example graph illustrating losses when a stub area is included and when a stub area is removed in a contact hole assembly according to embodiments; and

FIG. 11 is an example view illustrating a process of removing a stub area in a contact hole assembly according to another embodiment of the disclosure.

### DETAILED DESCRIPTION

Hereinafter, some embodiments of the disclosure will be described in detail with reference to exemplary drawings. In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure will be described in detail with reference to the accompanying drawings.

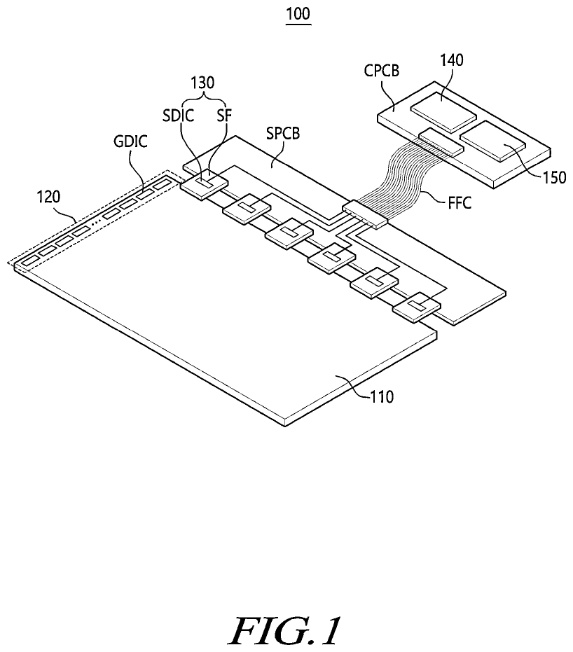

FIG. 1 is a view illustrating a display device as an example of an electronic device including a contact hole assembly.

Referring to FIG. 1, a display device 100 may include a gate driving circuit 120 supplying a scan signal to a display panel 110, a data driving circuit 130 supplying a data voltage to the display panel 110, a timing controller 140 controlling the gate driving circuit 120 and the data driving circuit 130, and a power management circuit 150 supplying a driving voltage.

It is herein illustrated that the source driving integrated circuit SDIC constituting the data driving circuit 130 is implemented in a chip-on-film (COF) type among various types (e.g., TAB, COG, or COF), and the gate driving integrated circuit GDIC constituting the gate driving circuit 120 is implemented in a gate-in-panel (GIP) type among various types (e.g., TAB, COG, COF, or GIP).

When the gate driving circuit 120 is implemented in the GIP type, the plurality of gate driving integrated circuits GDIC included in the gate driving circuit 120 may be directly formed in the bezel area of the display panel 110. In this case, the gate driving integrated circuits GDIC may receive various signals (e.g., a clock signal, a gate high signal, a gate low signal, etc.) necessary for generating scan signals through gate driving-related signal lines disposed in the bezel area.

Likewise, one or more source driving integrated circuits SDIC included in the data driving circuit 130 each may be mounted on the source film SF, and one side of the source film SF may be electrically connected with the display panel 110. Lines for electrically connecting the source driving integrated circuit SDIC and the display panel 110 may be disposed on the source film SF.

The display device 100 may include at least one source printed circuit board SPCB for circuit connection between a plurality of source driving integrated circuits SDIC and other devices and a control printed circuit board CPCB for mounting control components and various electric devices.

The other side of the source film SF where the source driving integrated circuit SDIC is mounted may be connected to at least one source printed circuit board SPCB. In other words, one side of the source film SF where the source driving integrated circuit SDIC is mounted may be electrically connected with the display panel 110, and the other side thereof may be electrically connected with the source printed circuit board SPCB.

The timing controller 140 and the power management circuit 150 may be mounted on the control printed circuit board CPCB. The timing controller 140 may control the operation of the data driving circuit 130 and the gate driving circuit 120. The power management circuit 150 may supply driving voltage or current to the display panel 110, the data driving circuit 130, and the gate driving circuit 120 and control the supplied voltage or current.

At least one source printed circuit board SPCB and control printed circuit board CPCB may be circuit-connected through at least one connection member. The connection member may include, e.g., a flexible printed circuit FPC or a flexible flat cable FFC. The at least one source printed circuit board SPCB and control printed circuit board CPCB may be integrated into a single printed circuit board.

The power management circuit 150 transfers a driving voltage necessary for display driving or characteristic value sensing to the source printed circuit board SPCB through the flexible printed circuit FPC or flexible flat cable FFC. The driving voltage transferred to the source printed circuit board SPCB is supplied to emit light or sense a specific subpixel SP in the display panel 110 through the source driving integrated circuit SDIC.

Each of the subpixels SP arranged in the display panel 110 in the display device 100 may include a light emitting element and a circuit element, e.g., a driving transistor, for driving the organic light emitting diode.

The type and number of circuit elements constituting each subpixel SP may be varied depending on functions to be provided and design schemes.

In this case, metal layers constituting various signal lines may be formed on the source printed circuit board or the control printed circuit board, and metal layers formed on different layers may be electrically connected through contact holes.

Recently, as electronic devices tend to become slimmer, the thickness of printed circuit board on which various signal lines are disposed has decreased. When the thickness of the printed circuit board decreases, the gap between the signal lines decreases, resulting in an increase in capacitance and a decrease in impedance formed between the signal lines.

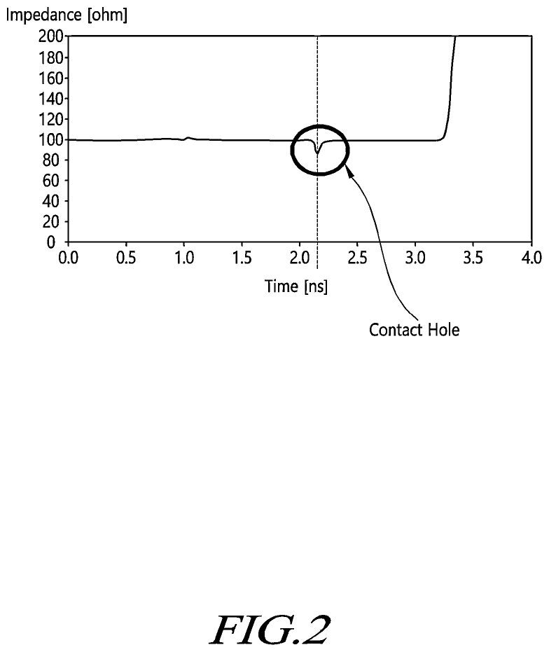

FIG. 2 is an example graph obtained by measuring the impedance of a printed circuit board in a time domain.

Referring to FIG. 2, a printed circuit board on which various signal lines are formed may efficiently transfer power when the input impedance of the portion to which the signal is input and the output impedance of the portion to which the signal is output are matched. However, when impedance mismatch occurs at a specific position of the printed circuit board, power loss increases.

A contact hole formed in the printed circuit board connects the upper metal layer and the lower metal layer through a conductor, and when the thickness of the printed circuit board decreases, impedance may be reduced due to an increase in capacitance.

When a pulse signal is applied to the printed circuit board using a time domain reflectometer (TDR), an impedance characteristic of the printed circuit board may be detected by observing the signal reflected from the printed circuit board. In this case, when the capacitance of the contact hole at the specific position increases, the impedance signal observed in the TDR decreases.

The contact hole assembly of the disclosure may have a recess structure in the contact hole in which impedance decreases in the printed circuit board, thereby reducing power consumption and enhancing impedance matching characteristics.

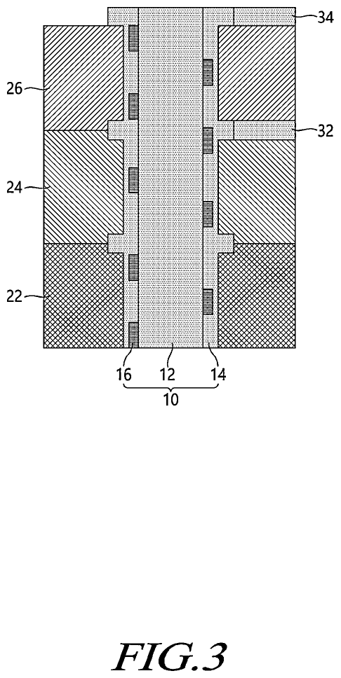

FIG. 3 is an example cross-sectional view illustrating a contact hole assembly according to embodiments of the disclosure.

Referring to FIG. 3, a contact hole assembly according to embodiments of the disclosure may electrically connect a first metal layer 32 and a second metal layer 34 through a contact hole 10.

To that end, a second insulation layer 24 may be formed on a first insulating material layer 22 such as a substrate, and the first metal layer 32 may be formed on the second insulation layer 24. The first metal layer 32 may be formed on the first insulating material layer 22.

In this case, a third insulation layer 26 may be formed on the second insulation layer 24 to cover the first metal layer 32, and the second metal layer 34 may be formed on the third insulation layer 26. The third insulation layer 26 covering the first metal layer 32 may be formed as a single layer or may be formed as a plurality of stacked layers.

Thereafter, a via area 12 is formed by disposing a mask having a transmissive portion on the second metal layer 34 to correspond to the contact hole area and etching the first insulation layer 22, the second insulation layer 24, the first metal layer 32, the third insulation layer 26, and the second metal layer 34.

Here, etching process using the mask may be performed to form the via area 12 by dry etching using a plasma etching gas considering anisotropy. In this case, in order to uniformly form another contact hole 10 in another adjacent area while forming the contact hole 10, etching of the insulation layers 22, 24, and 26 and the metal layers 32 and 34 may be performed under an over etching condition.

By forming a conductor 14 such as copper on the inner surface of the via area 12, a contact hole 10 electrically connecting a portion of the first metal layer 32 and a portion of the second metal layer 34 may be formed. In one embodiment, the via area 12 and the conductor 14 extend from the third insulation layer 26 to the first insulation layer 22. Since the conductor 14 extends from the third insulation layer 26 to the first insulation layer 22, the recess area 16 is surrounded by the first insulation layer 22, the second insulation layer 24, and the third insulation layer 26.

In this case, the inner surface of the conductor 14 constituting the contact hole 10 may include a recess area 16 along the inner surface where portions of the conductor 14 are partially removed. A portion of a surface of the conductor 16 may be removed in the recess area 16. That is, the recess area 16 of the conductor 14 is where a portion of a surface of the conductor is indented in a direction away from the via area 12. As a result, a width of a portion of the conductor 14 having the recess area 16 is less than a width of portion of the conductor 14 that lacks the recess area 16. The conductor 14 also has an outer surface that has a diameter that is greater than a diameter of the inner surface of the conductor 14. In one embodiment, a diameter of the recess area 16 is greater than the diameter of the inner surface of the conductor 14 and less than the diameter of the outer surface of the conductor 14.

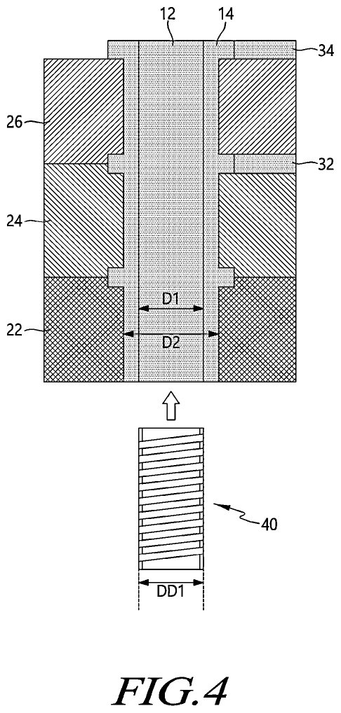

FIG. 4 is an example view illustrating a process of forming a contact hole assembly according to embodiments.

Referring to FIG. 4, in the contact hole assembly according to embodiments of the disclosure, in a state in which the conductor 14 electrically connecting the first metal layer 32 and the second metal layer 34 is formed in the via area 12, the recess area 16 may be formed in the inner surface of the conductor 14 using a drill 40.

The diameter DD1 of the drill 40 used to form the recess area 16 may be larger than the inner diameter D1 of the contact hole 10 formed by the conductor 14 and smaller than the outer diameter D2 of the contact hole 10.

In this case, the area of the recess area 16 constituting the contact hole 10 may vary depending on the position where the drill 40 is inserted in the inner surface of the conductor 14.

The impedance of the contact hole 10 may vary depending on the ratio of the area occupied by the recess area 16 to the inner surface area of the conductor 14.

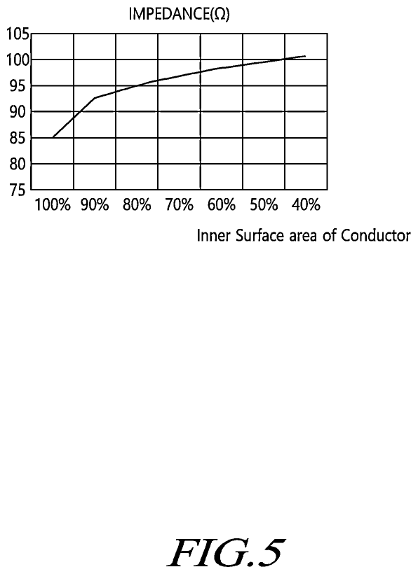

FIG. 5 is an example graph illustrating a change in impedance according to a recess area ratio in a contact hole assembly according to embodiments.

Referring to FIG. 5, in the contact hole assembly according to embodiments of the disclosure, as the area occupied by the recess area 16 in the inner area of the via area 12 increases, the capacitance formed by the conductor 14 decreases and the impedance increases. In other words, as the internal surface area of the conductor 14 except for the area occupied by the recess area 16 decreases, the impedance of the contact hole 10 increases.

Accordingly, by controlling the area of the recess area 16 formed in the inner surface of the conductor 14 of the contact hole 10, the impedance of the contact hole 10 may be increased and the impedance matching characteristics may be enhanced.

In this case, for effective transmission of the signal transferred through the contact hole 10, the inner surface area of the conductor 14 may occupy 40% or more and 60% or less of the inner surface area of the via area 12. In other words, the recess area 16 may occupy 40% to 60% of the inner surface area of the via area 12.

In a state in which the first metal layer 32 and the second metal layer 34 are electrically connected to each other by the contact hole 10 including the recess area 16, a current flowing through the first metal layer 32 flows to the second metal layer 34 along the contact hole 10.

In this case, the recess area 16 formed in the inner surface of the conductor 14 may have various shapes.

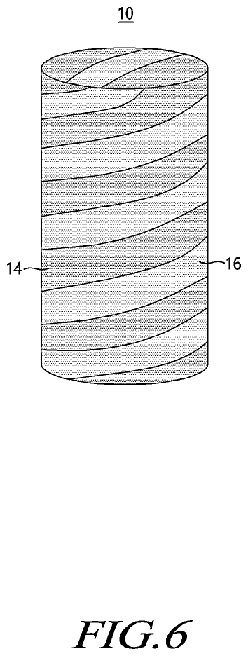

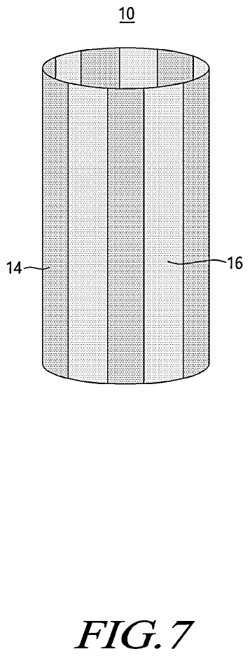

FIGS. 6 and 7 are example views illustrating a shape of a contact hole according to embodiments.

Referring to FIG. 6, the contact hole 10 according to embodiments of the disclosure may include a recess area 16 having a spiral structure. As a result, the conductor 14 has a spiral structure recess area 16.

The spiral recess area 16 may be formed by rotating the drill 40 while moving upward from the lower portion of the contact hole 10. In this case, the width and area of the recess area 16 may vary depending on the surface shape of the drill 40.

Further, referring to FIG. 7, the contact hole 10 according to embodiments of the disclosure may include a recess area 16 having a straight structure. As a result, the conductor 14 has a straight structure recess area 16. That is, the recess areas 16 with the straight structure extend along a length of the inner surface of the conductor 14 from a first end of the conductor 14 to a second end of the conductor 14 that is opposite the first end.

The straight recess area 16 may be formed by moving the drill 40 upward without rotating the drill 40 at the lower portion of the contact hole 10. Even in this case, the width and area of the recess area 16 may vary depending on the surface shape of the drill 40.

The shape of the spiral structure or the straight structure disclosed herein is merely an example of the recess area 16, and the recess area 16 of the contact hole 10 may have other various shapes such as a hatch structure depending on the surface shape of the drill 40, the moving direction and the rotating direction of the drill 40. The recess area 16 may be formed along a moving direction or a rotating direction of the drill 40.

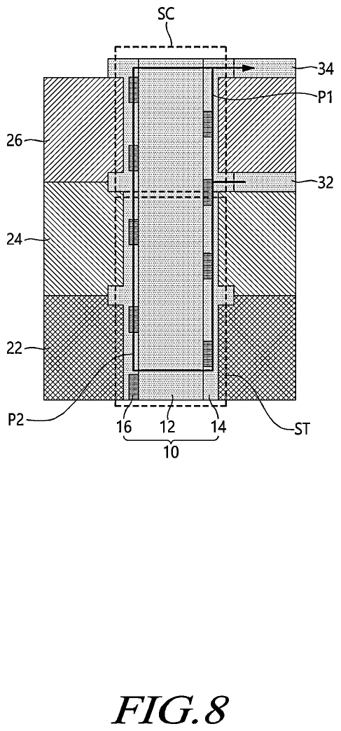

FIG. 8 is an example cross-sectional view illustrating a signal transmission path in a contact hole assembly according to embodiments.

Referring to FIG. 8, a contact hole assembly according to embodiments of the disclosure may electrically connect a first metal layer 32 and a second metal layer 34 through a contact hole 10.

In this case, the contact hole 10 may include a shortcut area SC having a shortest path P1 from a portion (e.g., the first metal layer 32) to which an electrical signal is input to a portion (e.g., the second metal layer 34) to which an electrical signal is output, and may also include a stub area ST having a detour path P2 from the first metal layer 32 to which a signal is input to the second metal layer 34 to which a signal is output.

Due to the stub area of the contact hole 10, the transmission characteristics of the signal transferred from the first metal layer 32 to the second metal layer 34 are deteriorated, and power consumption is increased. The transmission characteristic may deteriorate as the frequency of the signal transferred from the first metal layer 32 to the second metal layer 34 increases.

Accordingly, the contact hole assembly of the disclosure may enhance signal transmission characteristics by removing the stub area of the contact hole 10.

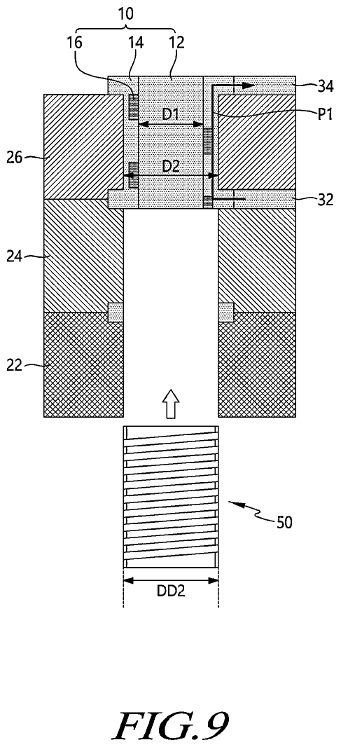

FIG. 9 is an example view illustrating a process of removing a stub area in a contact hole assembly according to embodiments.

Referring to FIG. 9, in the contact hole assembly according to embodiments of the disclosure, in a state in which the conductor 14 electrically connecting the first metal layer 32 and the second metal layer 34 is formed in the via area 12, the recess area 16 may be formed in the inner surface of the conductor 14 using a first drill having a first diameter.

The diameter of the first drill used to form the recess area 16 may be larger than the inner diameter D1 of the contact hole 10 formed by the conductor 14 and smaller than the outer diameter D2 of the contact hole 10.

In this case, the area of the recess area 16 constituting the contact hole 10 may vary depending on the position where the first drill is inserted in the inner surface of the conductor 14. Further, the impedance of the contact hole 10 may vary according to the ratio of the area occupied by the recess area 16 to the inner surface area of the conductor 14.

In a state in which the recess area 16 is formed in the inner surface of the conductor 14, the stub area ST of the contact hole 10 may be removed using a second drill 50 having a second diameter DD2.

The diameter DD2 of the second drill 50 used to remove the stub area ST may be equal to or larger than the outer diameter D2 of the contact hole 10. As a result, the diameter DD2 of the contact hole 10 that extends past the first metal layer 32 is wider than a diameter of the contact hole 10 from the second metal layer 34 to the first metal layer 32.

In this case, in the process of removing the stub area ST using the second drill 50, the first metal layer 32 to which the signal is input or the second metal layer 34 to which the signal is output should not be damaged. In other words, the stub area ST removed using the second drill 50 should not invade the first metal layer 32 to which the signal is input or the second metal layer 34 to which the signal is output. As a result of removing the stub area ST, the via area 12 and the conductor 14 extend from the second metal layer 34 to the first metal layer 32 without extending past the first metal layer 32 and the contact hole 10 extends from the second metal layer 34 past the first metal layer 32. That is, the via area 12 and the conductor 14 extend from the second metal layer 34 to the first metal layer 32 through the third insulation layer 26 without extending through the second insulation layer 24 and the first insulation layer 22. As a result, the recess area 16 is surrounded by the third insulation layer 26 without being surrounded by the second insulation layer 24 and the first insulation layer 22.

As described above, when the stub area ST of the contact hole 10 is removed, the signal input to the first metal layer 32 is transferred to the second metal layer 34 through the shortcut area SC including a first path P1, and thus power consumption may be reduced and transmission characteristics may be enhanced.

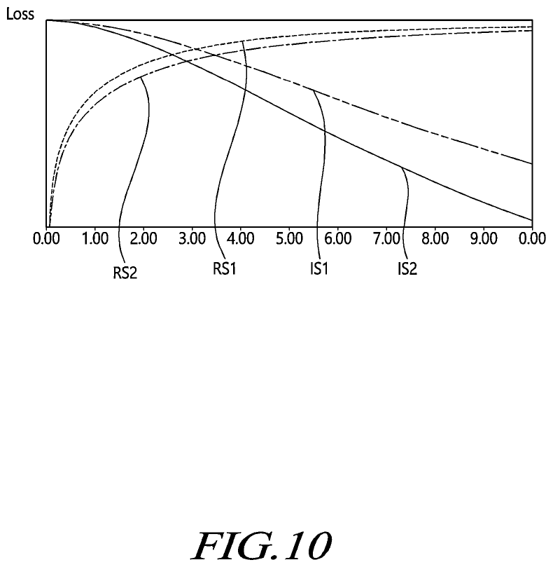

FIG. 10 is an example graph illustrating losses when a stub area is included and when a stub area is removed in a contact hole assembly according to embodiments.

Referring to FIG. 10, in the contact hole assembly according to embodiments of the disclosure, the stub area ST corresponding to the detour path between the first metal layer 32 to which the signal is input and the second metal layer 34 to which the signal is output may be removed.

In other words, the contact hole assembly according to embodiments of the disclosure may include only a shortcut area SC corresponding to the shortest path from the first metal layer 32 to which the signal is input to the second metal layer 34 to which the signal is output.

As described above, the input loss IS2 of the contact hole assembly including only the shortcut area SC is reduced compared to the input loss IS1 when the stub area ST is included, and this effect is more noticeable as the frequency of the input signal increases.

Further, the reflection loss RS2 of the contact hole assembly including only the shortcut area SC is reduced compared to the reflection loss RS1 when the stub area ST is included. However, the reduction amplitude of the reflection loss RS2 of the contact hole assembly including only the shortcut area SC increases within a range of a specific frequency.

As described above, the contact hole assembly of the disclosure, with the stub area ST removed, may reduce power consumption and enhance transmission characteristics during a signal transmission process.

As described above, in the contact hole assembly of the disclosure, in the contact hole 10 electrically connecting the first metal layer 32 and the second metal layer 34, the stub area ST may be removed in a state in which the recess area 16 is formed. On the other hand, in the contact hole assembly of the disclosure, the stub area ST may be removed in a state in which the conductor 14 is formed in the via area 12 of the contact hole 10 electrically connecting the first metal layer 32 and the second metal layer 34, and in a state in which the recess area 16 is not formed.

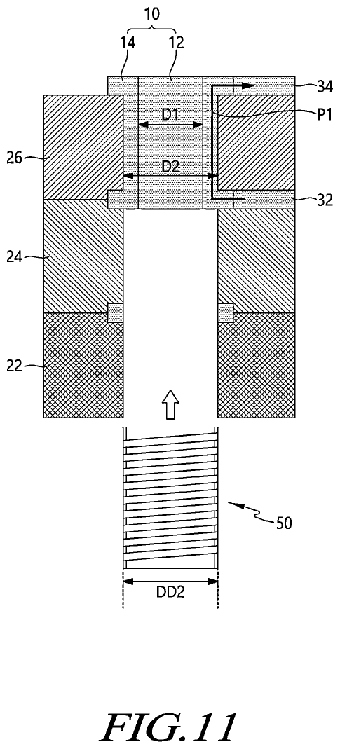

FIG. 11 is an example view illustrating a process of removing a stub area in a contact hole assembly according to another embodiment of the disclosure.

Referring to FIG. 11, in the contact hole assembly according to embodiments of the disclosure, a conductor 14 electrically connecting the first metal layer 32 and the second metal layer 34 may be formed in the via area 12.

In a state in which the conductor 14 is formed in the via area 12, the stub area ST of the contact hole 10 may be removed using the second drill 50 having the second diameter DD2.

The diameter DD2 of the second drill 50 used to remove the stub area ST may be equal to or larger than the outer diameter D2 of the contact hole 10.

In this case, in the process of removing the stub area ST using the second drill 50, the first metal layer 32 to which the signal is input or the second metal layer 34 to which the signal is output should not be damaged. In other words, the stub area ST removed using the second drill 50 should not invade the first metal layer 32 to which the signal is input or the second metal layer 34 to which the signal is output.

In short, the contact hole assembly of the disclosure may selectively include a structure in which the recess area 16 is formed and a structure in which the stub area ST is removed. Embodiments of the disclosure described above are briefly described below.

A contact hole assembly according to embodiments may comprise a first metal layer to which an electrical signal is input, an insulation layer formed on the first metal layer, a second metal layer formed on the insulation layer and outputting the electrical signal, and a contact hole electrically connecting the first metal layer and the second metal layer. The contact hole may include a via area penetrating the insulation layer, a conductor formed in the via area, and a recess area where a portion of a surface of the conductor is removed.

The via area may be formed by dry etching using plasma etching gas.

The recess area may be formed along a moving direction or a rotating direction of a drill.

A diameter of the drill may be larger than an inner diameter of the contact hole and smaller than an outer diameter of the contact hole.

The recess area may have a spiral structure or a straight structure.

The recess area may occupy 40% to 60% of an inner surface area of the via area.

The contact hole may include a shortcut area having a shortest path from the first metal layer to the second metal layer. A stub area having a detour path from the first metal layer to the second metal layer may be removed.

The stub area may be removed by a drill having a diameter larger than an outer diameter of the contact hole.

A contact hole assembly according to embodiments may comprise a first metal layer to which an electrical signal is input, an insulation layer formed on the first metal layer, a second metal layer formed on the insulation layer and outputting the electrical signal, and a contact hole electrically connecting the first metal layer and the second metal layer. The contact hole may include a shortcut area in which a conductor connecting the first metal layer and the second metal layer in a shortest path is formed. A stub area connecting the first metal layer and the second metal layer in a detour path may be removed.

The contact hole may include a via area penetrating the insulation layer, the conductor formed in the via area, and a recess area where a portion of a surface of the conductor is removed.

An electronic device according to embodiments may have a contact hole assembly comprising a first metal layer to which an electrical signal is input, an insulation layer formed on the first metal layer, a second metal layer formed on the insulation layer and outputting the electrical signal, and a contact hole electrically connecting the first metal layer and the second metal layer, wherein the contact hole includes a via area penetrating the insulation layer, a conductor formed in the via area, and a recess area where a portion of a surface of the conductor is removed.

The contact hole assembly may be formed on a printed circuit board.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A contact hole assembly, comprising:
a first metal layer that receives an electrical signal;
an insulation layer on the first metal layer;
a second metal layer on the insulation layer such that the insulation layer is between the first metal layer and the second metal layer, the second metal layer outputting the electrical signal; and
a contact hole that electrically connects the first metal layer and the second metal layer, the contact hole including:
a via area that penetrates through a thickness of the insulation layer;
a conductor in the via area; and
a recess area in the conductor where a portion of a surface of the conductor is indented in a direction away from the via area.

2. The contact hole assembly of claim 1, wherein the conductor includes an inner surface and outer surface that has a diameter that is greater than a diameter of the inner surface, and the recess area is disposed along the inner surface of the conductor.

3. The contact hole assembly of claim 2, wherein a diameter of the recess area is greater than the diameter of the inner surface of the conductor and less than the diameter of the outer surface of the conductor.

4. The contact hole assembly of claim 1, wherein the recess area has a spiral structure along an inner surface of the conductor or a straight structure along the inner surface of the conductor from a first end of the conductor to a second end of the conductor that is opposite the first end.

5. The contact hole assembly of claim 1, wherein the recess area occupies 40% to 60% of an inner surface area of the via area.

6. The contact hole assembly of claim 1, wherein the via area and the conductor extend from the second metal layer to the first metal layer without extending past the first metal layer and the contact hole extends from the second metal layer past the first metal layer.

7. The contact hole assembly of claim 6, wherein a diameter of the contact hole that extends past the first metal layer is wider than a diameter of the contact hole from the second metal layer to the first metal layer.

8. A contact hole assembly, comprising:
a first metal layer that receives an electrical signal;
an insulation layer on the first metal layer;
a second metal layer on the insulation layer such that the insulation layer is between the first metal layer and the second metal layer, the second metal layer outputting the electrical signal; and
a contact hole through the insulation layer, the contact hole electrically connecting the first metal layer and the second metal layer,
wherein the contact hole includes a conductor that is connected to the first metal layer and the second metal layer and extends from the second metal layer to the first metal layer whereas the contact hole extends from the second metal layer past the first metal layer.

9. The contact hole assembly of claim 8, wherein the contact hole includes:
a via area through an entire thickness of the insulation layer, the conductor in the via area; and
a recess area in the conductor where a portion of a surface of the conductor is indented in a direction away from the via area.

10. The contact hole assembly of claim 8, wherein a diameter of the contact hole that extends past the first metal layer is wider than a diameter of the contact hole from the second metal layer to the first metal layer.

11. An electronic device comprising:
a first metal layer that receives an electrical signal;
a first insulation layer on the first metal layer;
a second metal layer on the first insulation layer such that the first insulation layer is between the first metal layer and the second metal layer, the second metal layer outputting the electrical signal; and
a contact hole that electrically connects the first metal layer and the second metal layer, the contact hole including:
a via area that penetrates through a thickness of the first insulation layer;
a conductor in the via area; and
a recess area that extends from an inner surface of the conductor toward an outer surface of the conductor,
wherein a width of a portion of the conductor having the recess area is less than a width of a portion of the conductor that lacks the recess area.

12. The electronic device of claim 11, further comprising:
a printed circuit board that includes the first metal layer, the first insulation layer, the second metal layer, and the contact hole; and
a display panel including a plurality of subpixels that display an image, the display panel connected to the printed circuit board.

13. The electronic device of claim 11, wherein a diameter of the outer surface of the conductor is greater than the diameter of the inner surface of the conductor, and the recess area is disposed along the inner surface of the conductor.

14. The electronic device of claim 13, wherein a diameter of the recess area is greater than the diameter of the inner surface of the conductor and less than the diameter of the outer surface of the conductor.

15. The electronic device of claim 11, wherein the recess area has a spiral structure along the inner surface of the conductor or the recess area has a straight structure along the inner surface of the conductor from a first end of the conductor to a second end of the conductor that is opposite the first end.

16. The electronic device of claim 11, further comprising:
a second insulation layer; and
a third insulation layer on the second insulation layer such that the second insulation layer is between the first metal layer and the second insulation layer.

17. The electronic device of claim 16, wherein the via area and the conductor extend through the first insulation layer to the second insulation layer.

18. The electronic device of claim 17, wherein the recess area is surrounded by the first insulation layer, the second insulation layer, and the third insulation layer.

19. The electronic device of claim 16, wherein the via area and the conductor extend from the second metal layer to the first metal layer through the first insulation layer without extending through the second insulation layer and the third insulation layer.

20. The electronic device of claim 19, wherein the recess area is surrounded by the first insulation layer without being surrounded by the second insulation layer and the third insulation layer.
